(19) United States
(12) Patent Application Publication
(10) Pub. No.: US 2008/0303115 A1
(43) Pub. Date: Dec. 11, 2008

(54) SEMICONDUCTOR MEMORY DEVICE AND METHOD OF FABRICATING THE SAME

(75) Inventors: Shoichi MIYAZAKI, Yokkaichi (JP); Tadahito Fujisawa, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/134,576

(22) Filed: Jun. 6, 2008

(30) Foreign Application Priority Data
Jun. 6, 2007 (JP) 2007-150364

(51) Int. Cl. H01L 21/822; H01L 27/10

(52) U.S. Cl. 257/506; 438/587; 257/E27.07; 257/E21.606

(57) ABSTRACT

A semiconductor memory device includes a semiconductor substrate having a dummy cell region adjacent to a memory cell region, a plurality of memory cell transistors, a selective gate transistor, a peripheral circuit transistor, a selective gate line, a contact plug, a dummy contact plug formed in an element forming region of the memory cell region adjacent to the selective gate line, and a spacer insulating film formed on a sidewall of the peripheral circuit transistor. The sidewall of the selective gate electrode is formed with no spacer insulating film, and the selective gate line has a sidewall facing an region of the dummy cell region in which the dummy contact plug is formed, except for the sidewall of the selective gate electrode. The sidewall of the selective gate line is formed with a spacer insulating film.

### CROSS-REFERENCE TO RELATED APPLICATIONS

This application is based on and claims the benefit of priority from the prior Japanese Patent Application No. 2007-150364, filed on Jun. 6, 2007, the entire contents of which are incorporated herein by reference.

### BACKGROUND OF THE INVENTION

1. Field of the Invention

The present invention relates to a semiconductor memory device having a region in which a memory cell transistor with a gate electrode is formed, and a method of fabricating the same.

2. Description of the Related Art

NAND flash memories are known as the semiconductor memory device of the above-described type, for example. A memory cell transistor is required to be formed with a high integration degree in the NAND flash memories. For this purpose, a resolution close to a theoretical limit depending upon the wavelength of light has been obtained in a photolithography process of a fabrication process. Various types of phase shift mask methods have been considered to meet the foregoing requirement. A grazing incidence illumination has also been proposed as an exposure apparatus. In the grazing incidence illumination, a mask is illuminated by light falling thereon and inclined relative to an optical axis by an angle corresponding to the number of openings of a projection exposure system. Furthermore, exposure methods by the combination of phase shift mask method and grazing incidence illumination have been proposed.

The above-mentioned methods can achieve dramatic effects regarding high periodic patterns such as a simple line and space (L/S) pattern. However, the methods have difficulty in satisfying the resolution and depth of focus (DOF) in randomly located portions of a device pattern.

In view of the above-described problem, an improved exposure technique has recently been proposed which employs a mask disposing an unresolvable auxiliary pattern in a random pattern region. For example, Japanese patent application publication, JP-A-H07-140639, discloses a first method in which a mask for use in the projection exposure by the grazing incidence illumination is provided with an unresolvable pattern in addition to an aimed pattern. The above-mentioned publication also discloses a second method in which when an aimed pattern has periodicity, a mask forms an unresolvable auxiliary pattern or a group of patterns so that the periodicity is preserved. The publication further discloses a third method in which when an aimed pattern has no periodicity, a mask forms an unresolvable auxiliary pattern or a group of patterns so that periodicity is imparted to an aimed pattern.

The afore-referenced publication still further discloses, as a fourth method, a mask formed with one or more unresolvable auxiliary patterns each comprising a light-transmitting part and located away from a mask light-transmitting part edge by a pitch of 0.8 P to 1.4 P when an aimed pattern comprising a light-transmitting (or light-shielding) part has a width which is approximately equal to or larger than λ/2NA (=P) where λ is a wavelength of illumination light and NA is the number of apertures of projection lens in the second method. The publication further discloses, as a fifth method, a mask formed with one or more unresolvable auxiliary patterns each comprising a light-transmitting part and located away from one or both edges of an aimed pattern by a pitch of 0.8 P to 1.4 P when the aimed pattern comprising a non-periodic isolated light-transmitting part has a width which is approximately equal to or larger than P in the third method.

In the above-described configurations, expected results can be achieved when a pattern is formed by using a relatively simpler pitch. However, a pattern in the vicinity of a selective gate of a NAND flash memory, for example, includes a fine periodic pattern region, a periodic pattern region which is adjacent to the fine periodic pattern region and has a larger pattern width than the fine periodic pattern region or another periodic pattern region which has a further larger pattern width. Thus, patterns with various pitches are complexly intertwined with one another.

Furthermore, the resolution sometimes deteriorates due to presence of a non-periodic local region in the pattern formation of a selective gate electrode of the NAND flash memory device. In view of the deterioration of the resolution, Japanese patent application publication, JP-A-2004-348118, discloses a photomask formed with an auxiliary pattern adjacent to a primary pattern for the purpose of improving a lithography margin.

Although the foregoing drawbacks can be remedied in the contact forming process by the provision of the auxiliary pattern, the following other technical problems arise with progress in the refinement of design rules. More specifically, the fabrication of a NAND flash memory device includes a step of forming an ultra fine bit line contact between selective gate lines subsequent to formation of a memory cell. In the step, an auxiliary pattern needs to be set in a photomask in order that an ultra fine bit line contact may be formed. However, a contact hole is formed since a part of the photomask where the auxiliary pattern disposed as described above terminates is optically resolved into the resist. Accordingly, a dummy bit line contact is formed on a terminal end of an auxiliary pattern. In this case, there is a possibility that sidewalls of the selective gate line may be damaged. As a result, a short circuit would occur between the bit line contact and the selective gate line, whereupon the memory cell would malfunction.

### BRIEF SUMMARY OF THE INVENTION

In one aspect, the present invention provides a semiconductor memory device comprising a semiconductor substrate having a memory cell region, a dummy cell region adjacent to the memory cell region, and a peripheral circuit region, the memory cell region including a first element forming region and a second element forming region, a plurality of memory cell transistors having gate electrodes formed in the first element isolating region in the memory cell region with gate insulating films being interposed therebetween, a selective gate transistor provided in the first element forming region corresponding to an end of a group of a predetermined number of the memory cell transistors, the selective gate transistor having a selective gate electrode formed thereon with the gate insulating film being interposed therebetween, a peripheral circuit transistor formed in the second element forming region with a gate insulating film being interposed therebetween, the peripheral circuit transistor having a gate electrode, a selective gate line formed over the memory cell region, the dummy cell region and the peripheral circuit region, thereby electrically connecting the selective gate transistor to the peripheral circuit transistor, a contact plug electrically connected to the element forming region of the memory cell region adjacent to the selective gate electrode, a dummy contact plug formed in the element forming region of the memory cell region adjacent to the selective gate line, and a spacer insulating film formed on a sidewall of the gate electrode of the peripheral circuit transistor, wherein the sidewall of the selective gate electrode is formed with no spacer insulating film, and when the dummy cell region includes a first region in which the dummy contact plug is formed and a second region other than the first region, a spacer insulating film is formed on the sidewall of the second region.

In another aspect, the invention provides a method of fabricating a semiconductor memory device, comprising forming a gate insulating film and a gate electrode layer on a semiconductor substrate, forming an element isolation region by forming a trench in a surface layer of the semiconductor substrate and filling the trench with an insulating film, and subsequently forming memory cell gate electrodes of a memory cell region, a selective gate electrode, a gate electrode of a transistor of a peripheral circuit region, and a dummy gate electrode outside the memory cell gate region, burying an insulating film between the memory cell gate electrodes and forming first spacers comprising the insulating film on sidewalls of the selective gate electrode and the dummy gate electrode respectively, said sidewalls being opposed to each other, and further forming second spacers comprising the insulating film on sidewalls of the gate electrode of the transistor of the peripheral circuit region respectively, removing the first spacers formed on the sidewalls of the selective gate electrodes, said first spacers corresponding to a part in which a contact hole is to be formed to provide electrical connection between a part in which the selective gate electrodes are adjacent to each other and a surface of the semiconductor substrate, and further removing the first spacers of the dummy gate electrode located away by a predetermined distance from the memory cell region, and forming contact holes in the parts of the semiconductor substrate where the first spacers have been removed.

### BRIEF DESCRIPTION OF THE DRAWINGS

Other features and advantages of the present invention will become clear upon reviewing the following description of one embodiment with reference to the accompanying drawings, in which:

FIG. 1 is a schematic plan view of a memory cell region and a peripheral circuit region of a NAND flash memory device of one embodiment of the present invention;

FIG. 2 is a schematic plan view of a layout pattern of a part of the memory cell region;

FIGS. 3A and 3B are schematic sectional and plan views of a gate electrode SG between the memory cell region and a dummy dell region during the formation of a bit line contact;

FIG. 4 is a schematic plan view of the gate electrode SG between the memory cell region and the dummy cell region after formation of spacers;

FIG. 5 is a schematic plan view of the gate electrode SG between the memory cell region and the dummy cell region after a spacer removal step;

FIG. 6 is a schematic sectional view (No. 1) taken along line 6-6 in FIG. 2, showing one stage of the fabrication process;

FIG. 7 is also a schematic sectional view (No. 2) taken along line 6-6 in FIG. 2, showing another stage of the fabrication process;

FIG. 8 is further a schematic sectional view (No. 3) taken along line 6-6 in FIG. 2, showing further another stage of the fabrication process;

FIGS. 9A and 9B are further schematic sectional views taken along line 6-6 in FIG. 2 and taken along line 9B-9B in FIG. 3B, respectively, showing still further another stage of the fabrication process;

FIGS. 10A and 10B are views similar to FIGS. 9A and 9B, showing another stage of the fabrication process, respectively;

FIGS. 11A and 11B are views similar to FIGS. 10A and 10B, showing further another stage of the fabrication process, respectively;

FIGS. 12A and 12B are views similar to FIGS. 10A and 10B, showing further another stage respectively;

FIGS. 13A and 13B are views similar to FIGS. 10A and 10B, showing further another stage respectively;

FIGS. 14A to 14C are views similar to FIGS. 10A and 10B at further another stage and a schematic sectional view of a transistor of the peripheral circuit, respectively;

FIGS. 15A to 15C are views similar to FIGS. 14A to 14C, showing another stage of the fabrication process, respectively; and

FIGS. 16A to 16C are views similar to FIGS. 14A to 14C, showing further another stage of the fabrication process, respectively.

### DETAILED DESCRIPTION OF THE INVENTION

An embodiment of the present invention will be described with reference to the accompanying drawings. The invention is applied to a NAND flash memory device in the embodiment. In the following description, identical or similar parts are labeled by the same reference numerals. The drawings typically illustrate the invention, and the relationship between a thickness and plane dimension, layer thickness ratio and the like differ from natural size.

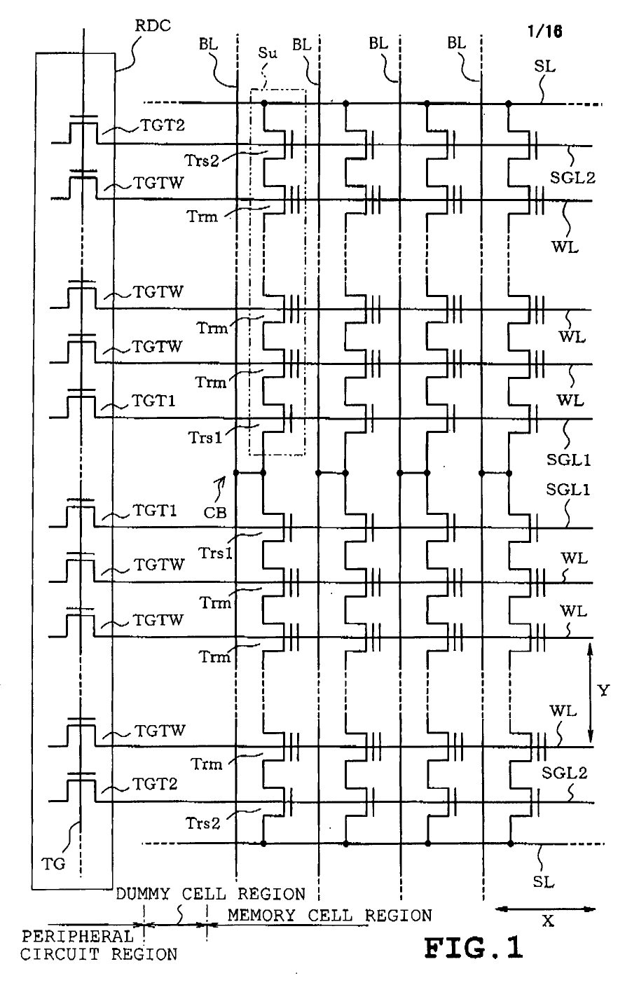

A configuration of the NAND flash memory device of the embodiment will first be described. FIG. 1 is a schematic plan view of a memory cell region and a peripheral circuit region of the NAND flash memory device. The NAND flash memory device includes a memory cell region in which a memory cell array is disposed. The memory cell array comprises a number of NAND cell units SU formed in rows and columns. Each NAND cell unit SU includes two selective gate transistors Trs1 and Trs2 and a plurality of memory cell transistors Trm series connected between the selective gate transistors Trs1 and Trs2. The number of the memory cell transistors Trm is represented as 2ⁿ where n is a positive number and, for example, 8 in the embodiment as shown in FIG. 1. In each NAND cell unit SU, source/drain regions are common to the memory cell transistors Trm adjacent to each other.

The memory cell transistors Trm are arranged in the X direction in FIG. 1 (corresponding to a word line direction and gate widthwise direction) and are connected in common by word lines (control gate lines) WL. Furthermore, selective gate transistors Trs1 are arranged in the x direction in FIG. 1 and connected in common by selective gate lines SGL1, and selective gate transistor Trs2 are connected in common by selective gate lines SGL2. Bit line contacts CB are connected to drain regions of the selective gate transistors Trs1. The bit line contacts CB are connected to bit line BL extending in the Y direction (corresponding to lengthwise direction of the gate and bit line direction) intersecting the X direction in FIG. 1. The selective gate transistors Trs2 are connected via source regions to source lines SL extending in the X direction in FIG. 1.

Each word line WL and each selective gate line SGL1, SGL2 are connected via a dummy cell region to a row decoder circuit RDC provided in a peripheral circuit region. The dummy cell region is adjacent to the memory cell region. The row decoder circuit RDC is connected to transfer gate transistors TGTW, TGT1 and TGT2 which are provided so as to correspond to the word lines WL and the selective gate line SGL1 and SGL2 respectively. The transfer gate transistors TGTW, TGT1 and TGT2 have respective gates connected in common to a transfer gate line TG.

A dummy cell region is provided for ensuring a necessary lithography margin. Dummy cells which are not used for normal data memory are formed in the dummy cell region. The dummy cell region includes a first dummy cell region provided between the peripheral circuit region and the memory cell region (on the left of the memory cell region in FIG. 1) and a second dummy cell region adjacent to a side of the memory cell region opposed to the first dummy cell region (on the right of the memory cell region in FIG. 1). The word lines WL and the selective gate lines SGL1 and SGL2 are terminated in the second dummy cell region.

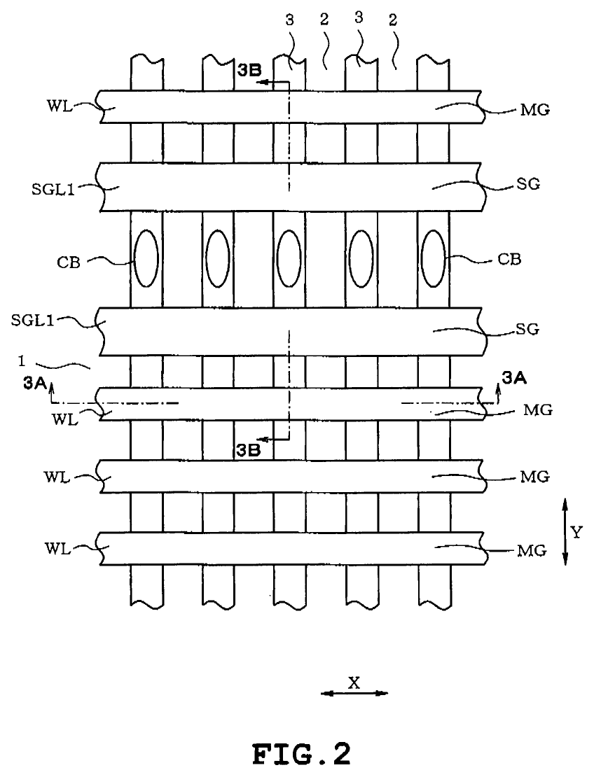

FIG. 2 is a plan view showing a layout pattern of part of the memory cell region. A plurality of insulating films 2 are formed by a shallow trench isolation (STI) method at predetermined intervals in a silicon substrate 1 so as to extend in the Y direction in FIG. 2. The insulating films 2 serve as element isolation regions. Each of these element isolation regions formed by the STI method will hereinafter be referred to as “STI.” The word lines WL of the memory cell transistors extend at predetermined intervals in the X direction intersecting active regions 3 as viewed in FIG. 2. A pair of selective gate lines SGL1 of the selective gate transistors are formed so as to extend in the X direction in FIG. 2. The bit line contacts CB are formed in the active regions 3 between the paired selective gate lines SGL1 respectively. Gate electrodes MG of the memory cell transistors are formed on the active regions 3 intersecting the word lines WL. The gate electrodes MG serve as first gate electrodes in the invention. Gate electrodes SG of the selective gate transistors are formed on the active regions 3 intersecting the selective gate lines SGL1. The gate electrodes SG serve as second gate electrodes.

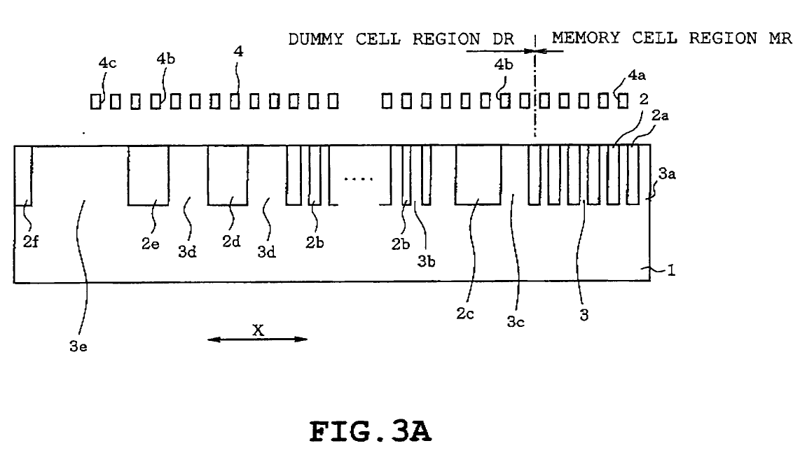

FIGS. 3A and 3B show a layout pattern of a section from an end of the memory cell region to the dummy cell region about the selective gate lines SGL1 and SL2. FIG. 3A is a sectional view taken along line 3A-3A in FIG. 3B which is a plan view. FIGS. 3A and 3B illustrate as a dummy cell region a first dummy cell region provided between the memory cell array region and the peripheral circuit region. A second dummy cell region having the same structure as the first dummy cell region is located opposite the first dummy cell region in the memory cell region.

A dummy cell region DR is provided adjacent to the memory cell region MR of the silicon substrate 1 in the X direction as shown in FIGS. 3A and 3B. Trenches 2a each having the STI structure are formed in the silicon substrate 1 of the memory cell region MR. The trenches 2a each of which has a predetermined width are formed at predetermined intervals, whereby first active regions 3a each of which has a predetermined width are formed on the silicon substrate 1 of the memory cell region MR. In a dummy cell region DR are formed dummy cell STIs 2b having the same width and formed at the same intervals as the STIs 2a of the memory cell region MR. Also, STIs 2c, 2d, 2e and 2f are formed on both sides of each dummy cell STI 2b. Each of the STIs 2c, 2d, 2e and 2f has a larger width than the STIs 2b. Furthermore, active regions 3b, 3c, 3d and 3e are formed in the dummy cell region DR. The active region 3b is located between the STIs 2b and has the same width as the active region 3a of the memory cell region MR. The active region 3c is located between the STIs 2a and 2c and between the STIs 2c and 2b and has a larger width than the active region 3b. The active region 3d is located between the STIs 2b and 2d and between the STIs 2d and 2e and has a larger width than the active region 3c. The active region 3e is located between the STIs 2e and 2f and has a larger width than the active region 3d. Thus, the active regions having larger and smaller widths are mixed in the dummy cell region DR. The active region 3b is provided for formation of the dummy cell. The active region 3c is provided for a boundary between the dummy cell region and the memory cell region. The active region 3d is provided for formation of a guard ring. The active region 3e is provided as a countermeasure against dishing. No dummy cell is formed in the active regions 3c, 3d and 3e.

Referring to FIG. 3B, a spacer SP1 is formed on a sidewall of the selective gate line SGL1 opposed to the selective gate line SGL2 in the dummy cell region. A spacer SP2 is formed on a sidewall of the selective gate line SGL2 opposed to the selective gate line SGL1. The spacers SP1 and SP2 are partially removed in a part DRp of the active region 3e with a larger width formed in the dummy cell region DR.

A bit line contact CB is formed in the active region 3a between the selective gate lines SGL1 and SGL2 in the memory cell region MR as described above. The bit line contact CB is formed using an elliptical or rectangular contact pattern 4a as shown in FIG. 3B. A mask pattern 4 for forming the contact pattern 4a includes the contact pattern 4a corresponding to the memory cell region MR and auxiliary patterns 4b and 4c corresponding to the dummy cell region DR. The auxiliary patterns 4b and 4c have the same shape as the contact pattern 4a and are arranged at the same intervals as the contact pattern 4a continuously from an end of the memory cell region MR. Furthermore, each of the auxiliary patterns 4b and 4c is made of a translucent pattern and is actually set so as not to be patterned by resist applied to the silicon substrate 1 during exposure. However, the auxiliary pattern 4c located at a terminal end is focused onto the resist due to optical characteristics thereof. Accordingly, a dummy contact hole equivalent to the bit line contact BC is formed. Another dummy contact hole is also formed in a second dummy region (not shown).

As the NAND flash memory device is configured as described above, the spacers SP1 and SP2 are not formed on the sidewalls of the selective gate lines SGL1 and SGL2 of a part MRp to be patterned in the formation of the bit line contacts CB. More specifically, the spacers SP1 and SP2 are removed from the sidewalls of the selective gate lines SGL1 and SGL2 opposed to each other, as shown by MRp and DRp, both in the memory cell region MR in which the bit line contact CB is actually formed by the contact pattern 4a and in a part in which a dummy contact hole is formed by the auxiliary pattern 4c. Consequently, when patterning is carried out in the photolithography process during formation of the bit line contact CB using the contact pattern 4, absence of the spacers SP1 and SP2 results in dimensional allowance during formation of a contact hole of the bit line contact pattern 4 even if occurrence of displacement of the contact pattern 4 causes the contact pattern 4 to come closer to the selective gate line SGL1 or SGL2 side. As a result, even if displacement of the contact pattern 4 occurs, a short circuit of the selective gate as seen in the conventional configuration can be prevented.

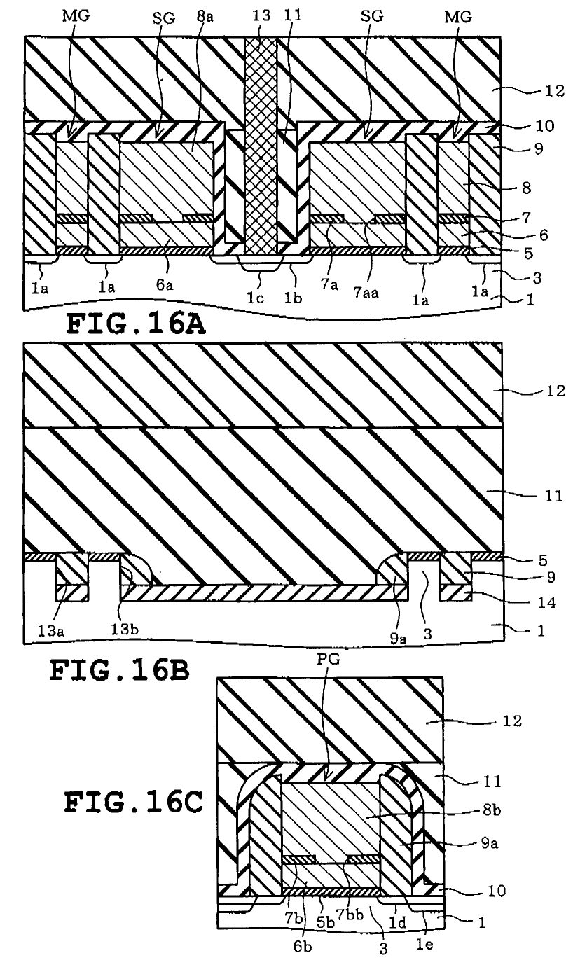

Referring now to FIG. 16A, the configuration of the memory cell region MR will be described. FIG. 16A is a schematic sectional view taken along line 10A-10A in FIG. 2 and more specifically shows a gate electrode SG of the selective gate transistor in the active region 3 of the memory cell region MR. The gate electrode MG of the memory cell transistor formed on the silicon substrate 1 comprises a polycrystalline silicon film 6 to be formed into a floating gate electrode, an intergate insulating film 7 comprising an oxide-nitride-oxide (ONO) film, and a polycrystalline silicon film 8 all of which are sequentially stacked via a silicon oxide film 5 serving as a gate insulating film, as shown in FIG. 16A. It is preferable to form a silicide layer such as cobalt silicide (Si₂Co) on the top of the polycrystalline silicon film 8 for the purpose of reduction in the wiring resistance although the silicide layer is not shown.

A gate electrode SC of the selective gate transistor comprises a polycrystalline silicon film 6a to be formed into a lower layer electrode, an intergate insulating film 7a comprising the same material as the intergate insulating film 7 and a polycrystalline silicon film 8a to be formed into an upper layer electrode all of which are sequentially stacked with the silicon oxide film 5 being interposed therebetween. The silicon oxide film 5 serves as the gate insulating film. The intergate insulating film 7 of the gate electrode SG is formed with an opening 7aa through which the polycrystalline silicon films 6a and 8a are rendered electrically conductive. The polycrystalline silicon film 8a is buried in the opening 7aa. A first impurity diffusion region 1a serving as a source/drain region is formed in a surface layer of the silicon substrate 1 between the gate electrodes MG and MG and between the gate electrodes MG and SG. A second impurity diffusion region 1b is formed on a surface layer of the silicon substrate 1 located between the gate electrodes SG. An impurity diffusion region 1c is formed for the purpose of a lithography doped drain (LDD) structure.

Silicon oxide films 9 are buried between the gate electrodes MG adjacent to each other and between the gate electrodes MG and SG by the low pressure chemical vapor deposition (LPCVD) respectively. The silicon oxide films 9 serve as interelectrode insulating films and are formed so as to protrude slightly from the upper surfaces of the gate electrodes MG and SG respectively. Silicon nitride films 10 serving as barrier films are formed on the upper surfaces of the gate electrodes MG and SG and silicon oxide film 9, sidewalls of the gate electrodes SG adjacent to each other and the surfaces of the silicon substrate 1 between the gate electrodes SG. The silicon nitride films 10 have respective predetermined film thicknesses.

A silicon oxide film 11 comprising a boro-phospho-silicate glass (BPSG) film is buried between the silicon nitride films on the opposed portions of the paired gate electrodes SG. The silicon oxide film 11 has an upper surface located slightly lower than the upper surface of the silicon nitride film 10 on the gate electrode SG. A silicon oxide film 12 serving as an interlayer insulating film is formed on upper surfaces of the silicon oxide film 11 and silicon nitride film 10. The silicon oxide film 12 has a predetermined film thickness and an upper surface planarized. A contact plug 13 forming the aforesaid bit line contact CB is formed between the paired gate electrodes SG so as to extend through the silicon oxide films 12 and 11 and the silicon nitride film 10 thereby to reach the surface of the impurity diffusion region 1c of the silicon substrate 1. The contact plug 13 is formed by burying a metal such as tungsten (W) with a barrier metal being interposed therebetween. The barrier metal may be a titanium (Ti) film or titanium nitride (TiN) film.

The plural memory cell transistors Trm adjacent to each other in the direction of the bit line commonly have the impurity diffusion layer 1a serving as a source/drain. Furthermore, a plurality of memory cell transistors are provided so that a current path is series connected between the selective gate transistors, whereupon the memory cell transistors are selected by the selective gate transistors. The other selective gate transistor to be connected to the current path of the memory select transistor is not shown in FIG. 16A. Furthermore, the number of the memory cell transistors to be series connected between the selective gate transistors may be plural such as 8, 16 or 32, for example, and should not be limited by the illustrated embodiment.

FIG. 16B is a section of the active region 3d where no gate electrodes are formed in the dummy cell region DR as shown by line 9B-9B in FIG. 3B. In the shown region, a silicon oxide film 14 for formation of trench is buried in trenches 13a and 13b formed in the silicon substrate 1 so that STIs 2d with the STI structure are formed. The silicon oxide film 14 is buried so that a predetermined height is reached in the trenches 13a and 13b. The silicon oxide film 9 is buried so as to fill the narrow trench 13a, and spacers 9a are formed in the wider trench 13b. The silicon oxide film 11 is formed so as to have a predetermined film thickness, thereby covering upper portions of the spacers 9a. The silicon oxide film 11 has an upper surface which is planarized. A silicon oxide film 12 is formed on an upper surface of the silicon oxide film 11.

FIG. 16C is a schematic longitudinal section of transistors constituting the row decoder RDC provided in the peripheral circuit region and other control circuits. The transistor of the peripheral circuit region includes a gate electrode PG as the aforesaid selective gate transistor. The gate electrode PG is formed by sequentially stacking the polycrystalline silicon film 6b serving as a lower layer electrode, the intergate insulating film 7b, and the polycrystalline silicon film 8b with the silicon oxide film 5b being interposed between the polycrystalline silicon film 6b and the active region 3 and the first impurity diffusion regions 1d. The peripheral circuit region includes transistors with low breakdown voltages and transistors with high breakdown voltages. The silicon oxide films corresponding to the silicon oxide film 5b have film thicknesses differing according to the breakdown voltages.

The intergate insulating film 7b is formed with an opening 7bb through which the polycrystalline silicon films 6b and 8b are rendered electrically conductive. The polycrystalline silicon film 8b is buried in the opening 7bb. A spacer 9a is provided on the sidewall of the gate electrode PG. The spacer 9a is formed by processing the silicon oxide film 9 serving as an insulating film. First impurity diffusion regions 1d are formed in portions of the silicon substrate 1 located at both sides of the gate electrode PG respectively. Second impurity diffusion regions 1e are formed inside the first impurity diffusion regions 1d using the spacers 9a. The second impurity diffusion regions 1e are provided for forming a lightly doped drain (LDD) structure.

The silicon nitride film 10 serving as a barrier film is formed on the upper surfaces of the gate electrode PG and the silicon oxide film 9 and the surface of the silicon substrate 1. The silicon nitride film 10 has a predetermined thickness. The silicon oxide film 11 comprising a BPSG film is formed so as to extend from an upper surface of the silicon nitride film 10 to upper surface of the silicon nitride film 10 on the gate electrode PG. A silicon oxide film 12 with a predetermined film thickness is formed on the upper surfaces of the silicon oxide film 11 and the silicon nitride film 10. The silicon oxide film 12 serves as an interlayer insulating film and has an upper surface planarized.

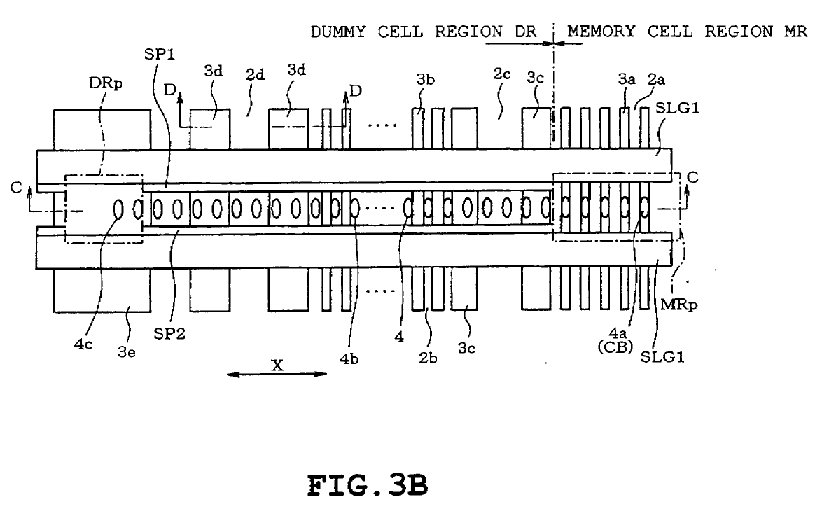

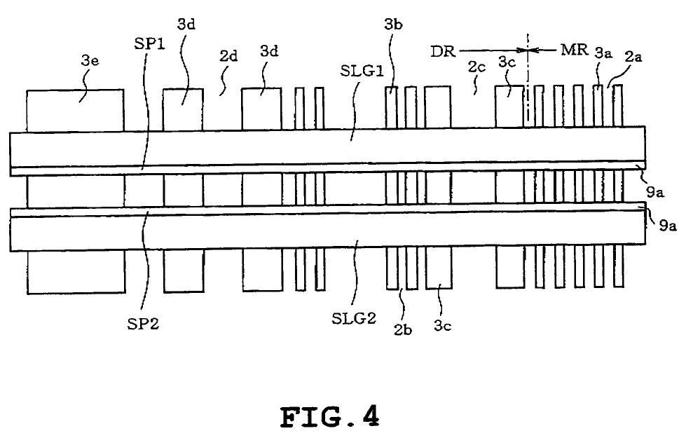

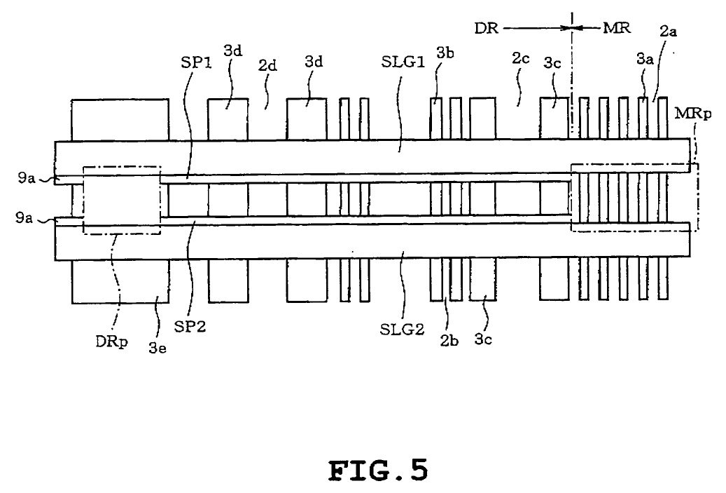

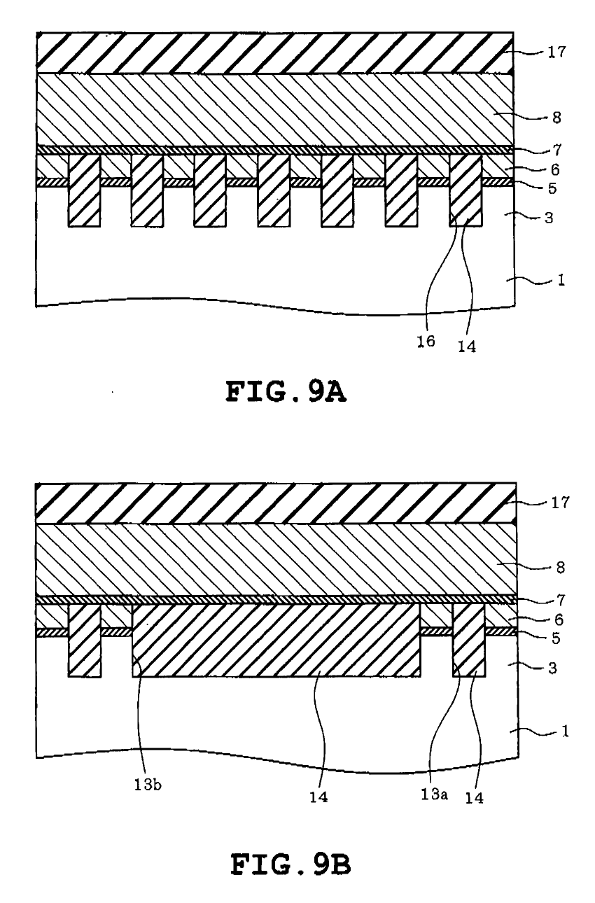

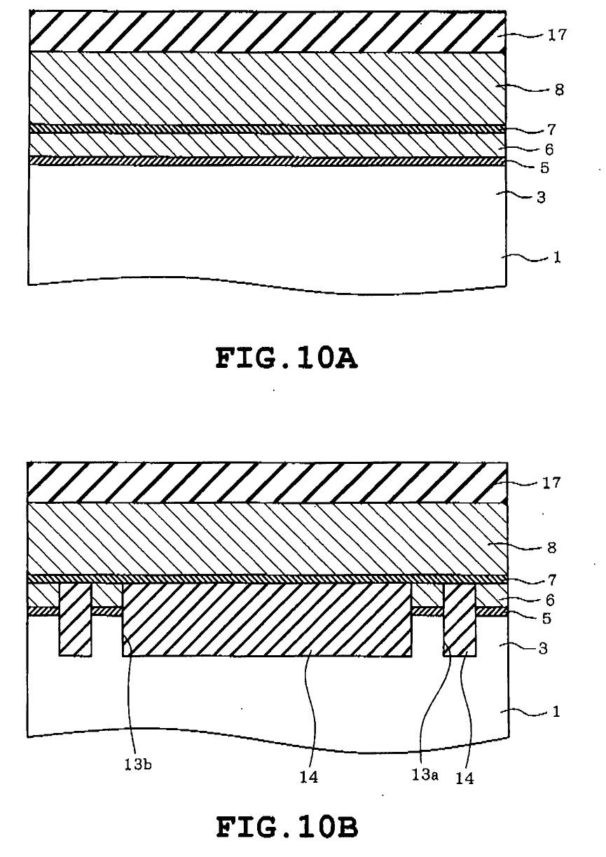

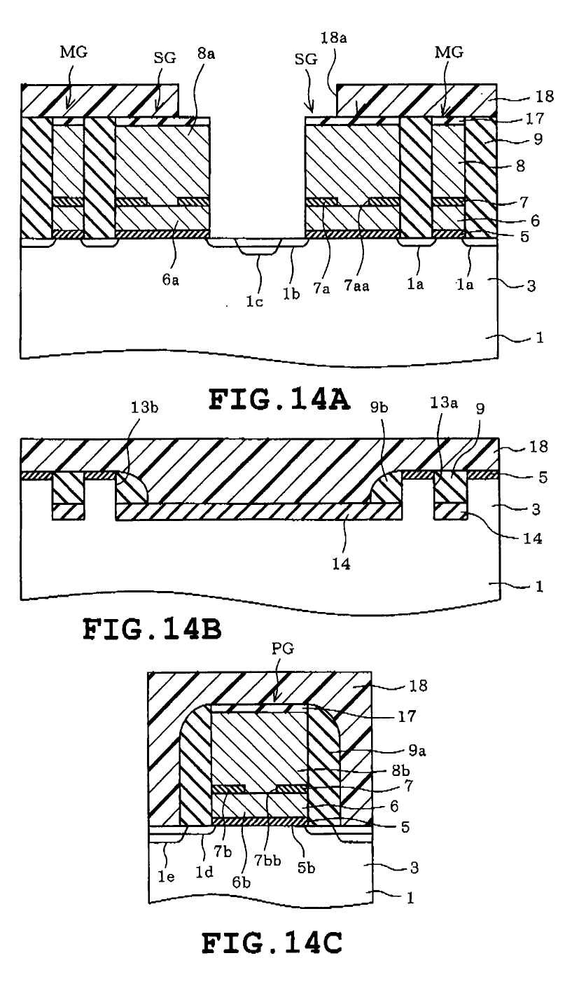

A process of fabricating the foregoing configuration will now be described with reference to FIGS. 4 to 16C. FIGS. 4 and 5 are plan views of the portion shown in FIG. 3B. FIGS. 6 to 9A are schematic sections of the portions taken along line A-A in FIG. 2. FIG. 9B is a schematic section of the portion of the peripheral circuit region or dummy cell region DR where the wider STI is formed. FIGS. 10A, 11A, 12A, 13A, 14A, 15A and 16A are schematic sections of the portion taken along line B-B in FIG. 2. FIGS. 10B, 11B, 12B, 13B, 14B, 15B and 16B are schematic sections of the portion corresponding to FIG. 9B. FIGS. 14C, 15A and 16C are schematic sections of the portion of the transistor of the peripheral circuit region.

Firstly, the silicon oxide film 5 with a film thickness of 10 nm is formed on the p-type silicon substrate 1 by thermal oxidation as shown in FIG. 6. Subsequently, the polycrystalline silicon film 6 serving as a floating gate is formed on the silicon oxide film 5 by a low pressure chemical vapor deposition (LPCVD) process with phosphor (P) being added as impurity. The polycrystalline oxide film 6 has a film thickness of 80 nm. The silicon nitride film 15 is formed on the polycrystalline oxide film 6. The silicon nitride film 15 serves both as a hard mask material for etching and as a stopper in the chemical mechanical polishing (CMP) process.

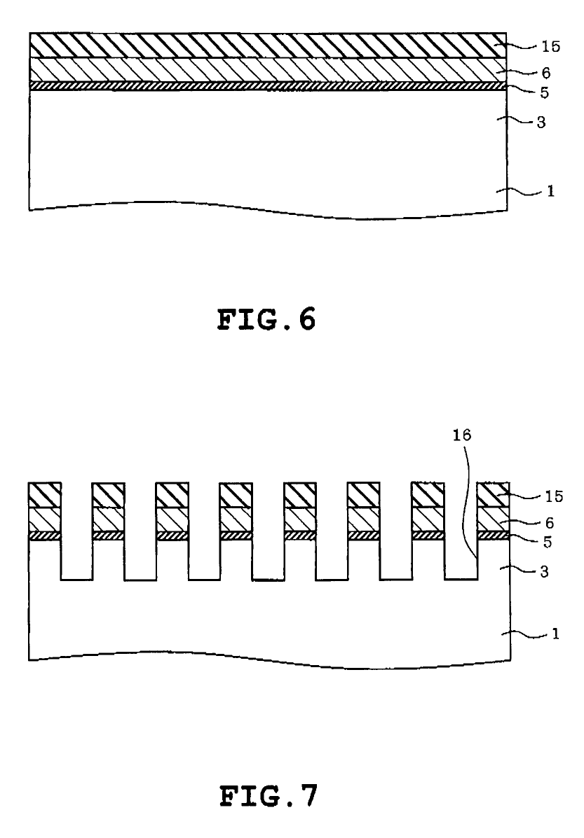

Subsequently, resist is patterned by a photolithography process as shown in FIG. 7. A dry etching process such as reactive ion etching (RIE) is carried out to sequentially etch the silicon nitride film 15, the polycrystalline silicon film 6, the silicon oxide film 5 and the silicon substrate 1, so that the trench in the memory cell region is formed or the aforesaid trenches 13a and 13b are formed in the silicon substrate 1 to be formed into the STI 2b in the dummy cell region.

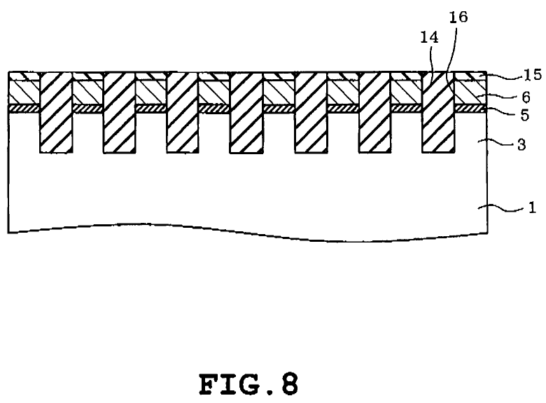

Subsequently, the silicon oxide film 14 is deposited so that an element isolation region with the STI structure is formed, as shown in FIG. 8. A coating type oxide film is sometimes used as the silicon oxide film 14 in order that the trench 16 with a high aspect ratio may be buried completely. In this case, an etching rate of the silicon oxide film 14 is increased relative to a wet process. The deposited silicon oxide film 14 is then polished by the CMP process and planarized with the silicon nitride film 6 serving as a stopper except for the silicon oxide film in the trench 16.

Subsequently, the intergate insulating film 7 is formed on the upper surface of the planarized silicon substrate 1 by the LPCVD process as shown in FIGS. 9A, 9B, 10A and 105. FIGS. 9B and 10B show the same part. The polycrystalline silicon film 8 is formed on the intergate insulating film 7 in the same manner as the floating gate electrode. The polycrystalline silicon film 8 is added with phosphor as an impurity and has a thickness of 200 nm. The polycrystalline silicon film 8 is formed into a control gate electrode. Furthermore, a silicon nitride film 17 for formation of a gate electrode is deposited.

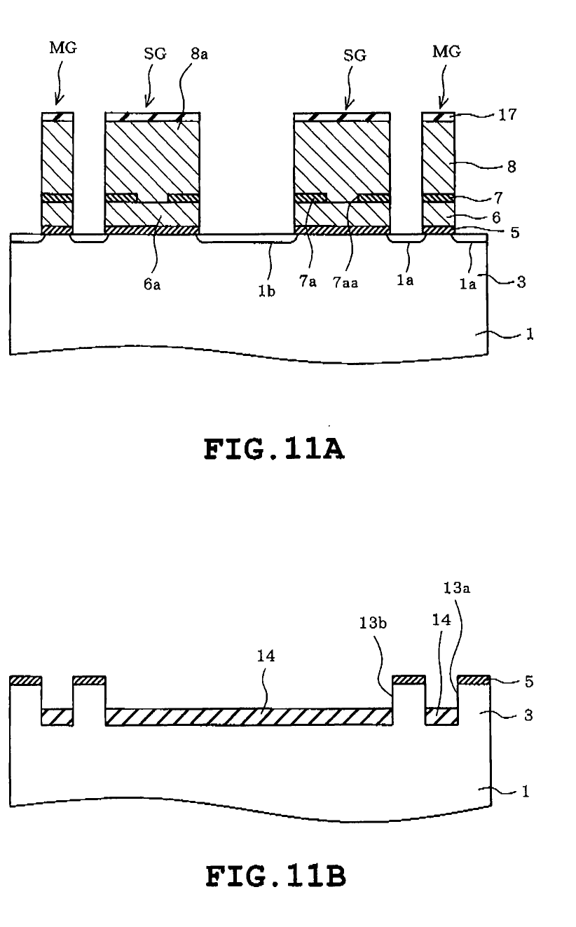

Subsequently, the resist is patterned by the photolithography process, and the silicon nitride film 17 is processed by the RIE process with the patterned resist serving as a mask, as shown in FIG. 11A. Subsequently, the polycrystalline silicon film 8a, the intergate electrode film 7a, the polycrystalline silicon film 6a and the silicon oxide film 5 are vertically etched with the processed silicon nitride film 17 serving as a hard mask, whereby a gate electrode structure is formed. The silicon oxide film 5 may remain. In this case, etching applied to the silicon oxide film 14 formed in the trenches 13a and 13b by the RIE process reaches a location lower than the upper surface of the silicon substrate 1, as shown in FIG. 11B. Subsequently, impurities are introduced into the portion of the silicon substrate 1 between the gate electrodes MG and SG by ion implantation, whereby the impurity diffusion regions 1a and 1b serving as source/drain regions are formed.

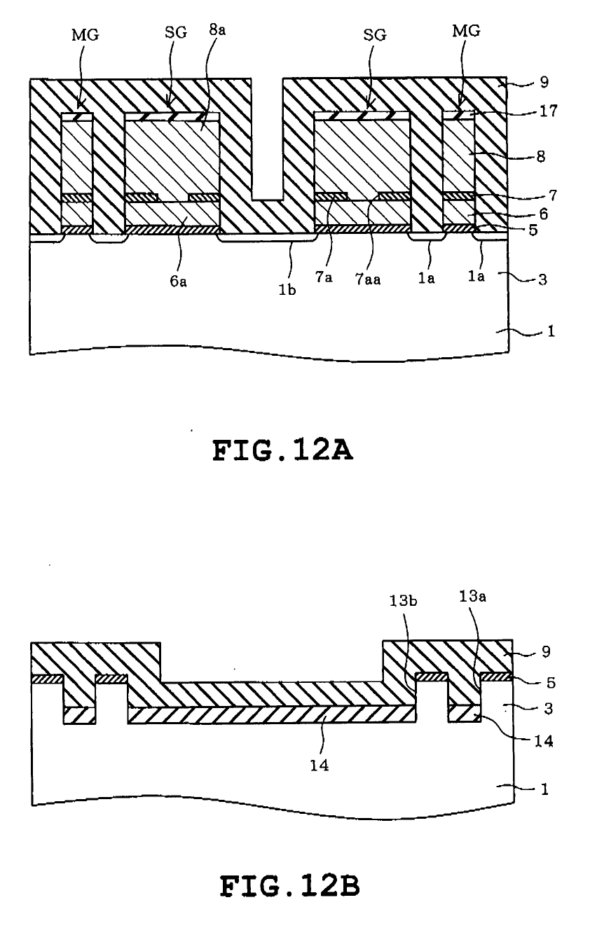

Subsequently, in order that a sidewall structure necessary for formation of a diffusion layer may be formed, the silicon oxide film 9 is deposited on the silicon substrate 1 so as to bury between the gate electrodes MG and MG and the gate electrodes MG and SG and so as to cover the sidewalls between the gate electrodes SG and SG and the surface of the silicon substrate 1, as shown in FIGS. 12A and 12B. In this case, although the section between the gate electrodes MG and MG is filled with the silicon oxide film 9, the section between the gate electrodes SG and SG is not filled with the silicon oxide film 9. Accordingly, the film thickness of the silicon oxide film 9 is set at such a value that a recess is formed.

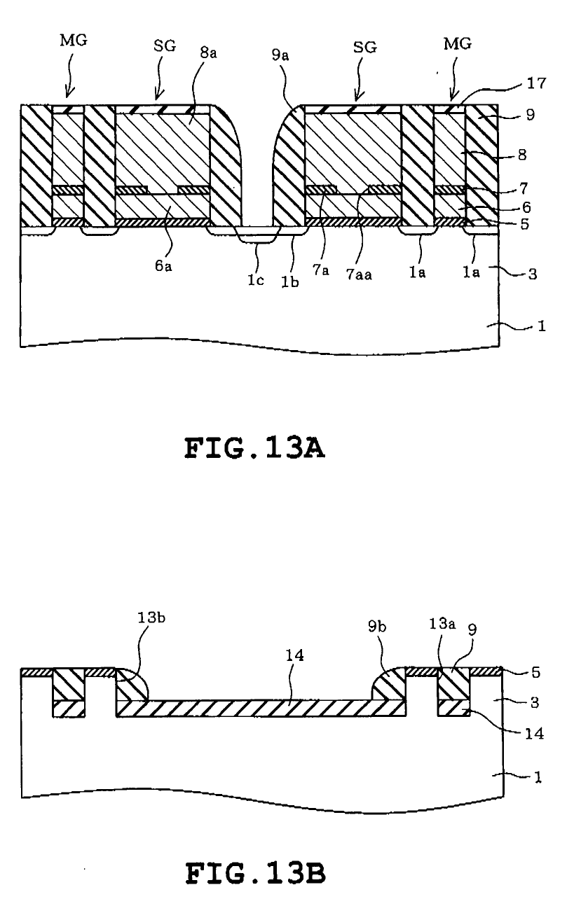

Subsequently, the silicon oxide film 9 is vertically etched by the RIE process so that the silicon oxide film selectively remains on the sidewalls in the portion where the gate electrodes SG are opposed to each other, as shown in FIG. 13. In this etching process, furthermore, narrow portions such as the portion between the gate electrodes MG and MG and MG and SG and the trench 13a remain unetched. Wider trench 13b is completely removed except for the spacer 9b. Thus, high concentrated impurities are introduced into the silicon substrate 1 with the spacer 9a between the gate electrodes SG and SG serving as a mask, whereby the impurity diffusion region 1c is formed.

FIG. 4 is a schematic plan view of the dummy cell region DR except for the memory cell region SR after execution of the above-described steps. The spacers SP1 and SP2 are formed at the portions of the sidewalls at the sides where the selective gate lines SLG1 and SGL2 are opposed to each other, respectively. These spacers SP1 and SP2 are formed as the aforesaid spacers 9a. Subsequently, a resist 18 is applied and patterned so that the opening 18a (MRp in FIG. 5) is formed only between the gate electrodes SG and SG by the lithography process, as shown in FIG. 14A. Thereafter, in order that the bit line contact CB and the gate electrode SG may be prevented from occurrence of short circuit, the spacers 9a formed on the sidewalls between the gate electrodes SG and SG are selectively etched by a wet etching process or the like with the patterned resist 18 serving as a mask. In this case, since the silicon oxide film 14 with a higher etching rate is exposed in the wider trench region, the silicon oxide film 14 is covered with the resist 18 as shown in FIG. 14B. Furthermore, the transistor in the peripheral circuit is covered with the resist 18 so that the spacer 9a may remain unchanged, as shown in FIG. 14C.

In the above-described case, removal is also carried out by a removal pattern DAp in a wider active region 3e formed in the dummy cell region DA in the same manner as described above as shown in FIG. 5. As described above, the auxiliary patterns 4b and 4c are provided so as to correspond to the dummy cell region DR of the mask pattern in forming the bit line contact CB. The auxiliary pattern 4c located at the terminal end is focused onto the resist, and this region is formed as the opening DRp of the resist.

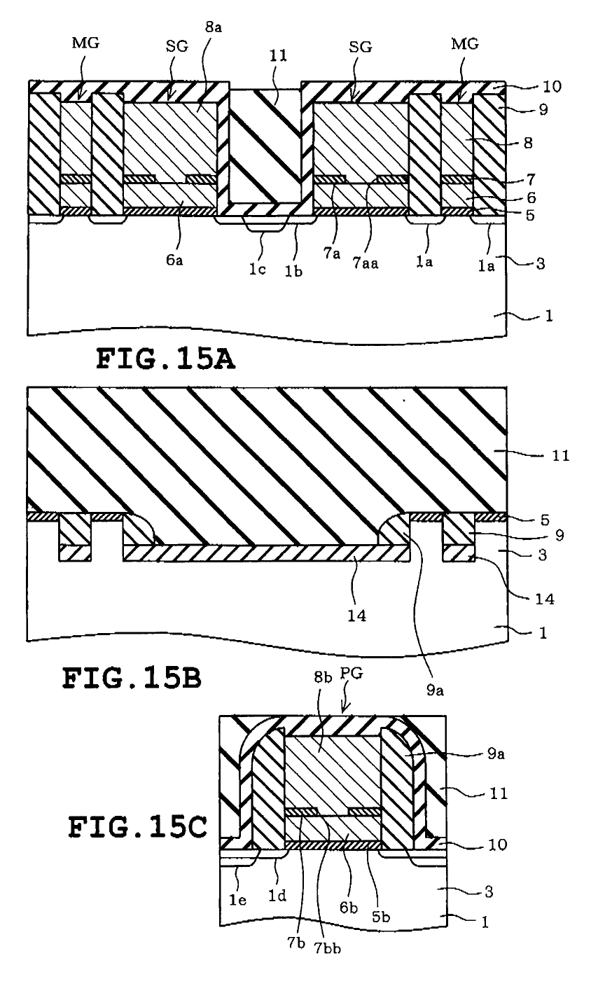

Subsequently, the silicon oxide film 11 is deposited as shown in FIGS. 15A to 15C. The silicon oxide film 11 comprises a silicon nitride film 10 serving as a contact stopper and BPSG serving as an intergate layer film. A planarization process is carried out by the CMP process with the silicon nitride films 10 and 17 serving as stoppers. Subsequently, the silicon oxide film 12 serving as an interwiring layer is deposited as shown in FIGS. 16A to 16C. Furthermore, the bit line contact CB is formed between the gate electrodes SG and SG by the photolithography process. In this case, a pattern 4a of the bit line contact CB has a minor axis of about 50 nm, and special auxiliary patterns 4b and 4c which are not focused onto the resist need to be added to the photomask 4. Finally, the silicon oxide films 12 and 11 and the silicon nitride film 10 are vertically processed so that the bit line contact CB is formed.

According to the foregoing embodiment, when the auxiliary patterns 4b and 4c are formed for the mask pattern during formation of the bit line contact CB, the spacer 9a in the region in which the bit line contact pattern 4b is formed is removed and at the same tine, the spacer 9a of that portion is removed. Accordingly, an allowance can be given to the patterning between the gate electrodes SG and SG or an offset can be ensured. Consequently, even when a dummy contact hole is formed on the resolved auxiliary pattern 4c, the terminal end can be prevented from occurrence of a short circuit between both gate electrodes SG.

The invention should not be limited by the foregoing embodiment. The embodiment can be modified or expanded as follows. The width of the trench with the STI structure in the dummy cell region DR may be set to a suitable value. In the foregoing embodiment, a region from which the spacer is to be removed is set only to the end on which the contact hole is to be formed by the auxiliary pattern. However, spacers in the entire region in which the auxiliary pattern is disposed may be removed, instead. Additionally, the charge storage layer should not be limited to the polycrystalline silicon film. For example, a silicon nitride film may be used as a charge storage layer, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor memory device comprising:
a semiconductor substrate having a memory cell region, a dummy cell region adjacent to the memory cell region, and a peripheral circuit region, the memory cell region including a first element forming region and a second element forming region;
a plurality of memory cell transistors having gate electrodes formed in the first element isolating region in the memory cell region with gate insulating films being interposed therebetween;
a selective gate transistor provided in the first element forming region corresponding to an end of a group of a predetermined number of the memory cell transistors, the selective gate transistor having a selective gate electrode formed thereon with the gate insulating film being interposed therebetween;
a peripheral circuit transistor formed in the second element forming region with a gate insulating film being interposed therebetween, the peripheral circuit transistor having a gate electrode;
a selective gate line formed over the memory cell region, the dummy cell region and the peripheral circuit region, thereby electrically connecting the selective gate transistor to the peripheral circuit transistor;
a contact plug electrically connected to the element forming region of the memory cell region adjacent to the selective gate electrode;
a dummy contact plug formed in the element forming region of the memory cell region adjacent to the selective gate line; and
a spacer insulating film formed on a sidewall of the gate electrode of the peripheral circuit transistor, wherein the sidewall of the selective gate electrode is formed with no spacer insulating film, and when the dummy cell region includes a first region in which the dummy contact plug is formed and a second region other than the first region, a spacer insulating film is formed on the sidewall of the second region.

2. A semiconductor memory device comprising:
a semiconductor substrate having a memory cell region in which a plurality of first element forming regions each extending in a predetermined direction are formed with respective element isolation regions being interposed therebetween, a peripheral circuit region in which a peripheral circuit transistor is formed, and a dummy cell region adjacent to the memory cell region, the dummy cell region having a second element forming region;
a selective gate line formed over the memory cell region, the dummy cell region, and the peripheral circuit region crosswise in said predetermined direction, thereby electrically connecting the selective gate transistor to the peripheral circuit transistor;
a contact plug electrically connected to the first element forming region adjacent to the selective gate electrode;
a dummy contact plug formed in the second element forming region, said second element forming region being adjacent to the selective gate line; and
a spacer insulating film formed on a sidewall of a gate electrode of the peripheral circuit transistor, wherein the selective gate line has a sidewall including a first portion which is located in the memory cell region, a second portion which is located in the dummy cell region where the dummy contact plug is formed and a third portion other than the first and second portions, the sidewall of the third portion being formed with a spacer insulating film.

3. The device according to claim 2, wherein the dummy cell region includes a first region located between the memory cell region and the peripheral circuit region and a second region located opposite the first region in the memory cell region, and two dummy contact plugs are provided in the first and second regions respectively.

4. A method of fabricating a semiconductor memory device, comprising:
forming a gate insulating film and a gate electrode layer on a semiconductor substrate, forming an element isolation region by forming a trench in a surface layer of the semiconductor substrate and filling the trench with an insulating film, and subsequently forming memory cell gate electrodes of a memory cell region, a selective gate electrode, a gate electrode of a transistor of a peripheral circuit region, and a dummy gate electrode outside the memory cell gate region;
burying an insulating film between the memory cell gate electrodes and forming first spacers comprising the insulating film on sidewalls of the selective gate electrode and the dummy gate electrode respectively, said sidewalls being opposed to each other, and further forming second spacers comprising the insulating film on sidewalls of the gate electrode of the transistor of the peripheral circuit region respectively;
removing the first spacers formed on the sidewalls of the selective gate electrodes, said first spacers corresponding to a part in which a contact hole is to be formed to provide electrical connection between a part in which the selective gate electrodes are adjacent to each other and a surface of the semiconductor substrate, and further removing the first spacers of the dummy gate electrode located away by a predetermined distance from the memory cell region; and
forming contact holes in the parts of the semiconductor substrate where the first spacers have been removed.

5. The method according to claim 4, wherein in the contact hole forming step, patterning is carried out using a photomask provided with a mask pattern for forming the contact holes of the memory cell region and an auxiliary pattern corresponding to a section from the memory cell region to a location where the first spacers are to be removed.
